(19) United States
(12) Patent Application Publication
(10) Pub. No.: US 2026/0173413 A1
(43) Pub. Date: Jun. 18, 2026

(54) METAL GATE METAL-INSULATOR-METAL (MIM) CAPACITOR WITH AIR SPACER AND METHOD FOR FABRICATING THE SAME

(71) Applicant: Taiwan Semiconductor Manufacturing Company, Ltd., Hsinchu (TW)

(72) Inventors: Ru-Shang Hsiao, Hsinchu (TW); Ke-Jing Yu, Kaohsiung (TW); Anhao Cheng, Taichung (TW); Yen-Liang Lin, Tainan (TW)

(21) Appl. No.: 18/981,672

(22) Filed: Dec. 16, 2024

(51) Int. Cl. H10D 1/68

(52) U.S. Cl. CPC H10D 1/696; H10D 1/716

(57) ABSTRACT

A semiconductor device includes: a substrate; a first interlayer dielectric (ILD) disposed on the substrate; and a metal-insulator-metal (MIM) capacitor disposed in the first ILD. The MIM capacitor comprises: a first metal layer disposed on the substrate; a first insulator layer comprising a horizontal portion and a sidewall portion; a second metal layer, wherein the horizontal portion of the first insulator layer is disposed between the first metal layer and the second metal layer, and the sidewall portion of the first insulator layer horizontally surrounding the second metal layer; a second insulator layer surrounding the sidewall portion of the first insulation layer; at least one metal contact extending vertically through the second insulator layer, wherein a lower end of the at least one metal contact is in contact with the first metal layer; and at least one air spacer horizontally surrounding the at least one metal contact.

### FIELD

Embodiments of the present disclosure relate generally to metal-insulator-metal (MIM) capacitors, and more particularly to front-end-of-line (FEOL) MIM capacitors with air spacers.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional diagram illustrating an example chip in accordance with some embodiments.

FIG. 1B is a diagram illustrating a top view of a portion of the chip of FIG. 1A in accordance with some embodiments.

FIG. 2 is a diagram illustrating a top view of a portion of another chip in accordance with some embodiments

FIG. 3 is a flowchart diagram illustrating an example method in accordance with some embodiments.

FIGS. 4A-4D are cross-sectional diagrams illustrating the cross-sections of the structures in various fabrication stages in accordance with some embodiments.

FIG. 5A is a cross-sectional diagram illustrating an example chip in accordance with some embodiments.

FIG. 5B is a diagram illustrating a top view of a portion of the chip of FIG. 5A in accordance with some embodiments.

FIG. 6A is a cross-sectional diagram illustrating an example chip in accordance with some embodiments.

FIG. 6B is a diagram illustrating a top view of a portion of the chip of FIG. 6A in accordance with some embodiments.

FIG. 7 is a flowchart diagram illustrating an example method in accordance with some embodiments.

FIGS. 8A-8D are cross-sectional diagrams illustrating the cross-sections of the structures in various fabrication stages in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Metal-insulator-metal (MIM) capacitors are a type of electronic component that store electrical energy. They are characterized by their simple structure, consisting of two metal electrodes separated by a thin insulating layer. This configuration allows for high capacitance values in a relatively small footprint. An MIM capacitor typically includes a top electrode, a bottom electrode, and an insulating layer. The top and bottom electrodes are typically made of conductive metals like aluminum, tantalum, or titanium. The insulating layer is often made of a dielectric material such as silicon nitride, tantalum oxide, or aluminum oxide. Its thickness determines the capacitance of the capacitor.

Advantages of MIM capacitors include high capacitance, low leakage current, high reliability, and wide operating voltage ranges. Accordingly, MIM capacitors are widely used for applications such as ICs (used to provide coupling, filtering, and storage functions), RF devices (e.g., filters, oscillators, and mixers), memory devices (e.g., DRAM, SRAM, and the like), and power electronics (used for decoupling, filtering, and energy storage).

Back-end-of-line (BEOL) MIM capacitors have been developed. BEOL MIM capacitors are integrated into the wiring layers of semiconductor devices. They offer a compact and efficient way to provide capacitance within the chip's structure, enhancing performance and functionality. BEOL MIM capacitors are seamlessly incorporated into the existing wiring layers of a chip, eliminating the need for separate components and reducing overall package size. They can achieve high capacitance values in a small area, enabling dense integration of components and improved circuit performance. Their integration within the chip's wiring layers minimizes parasitic effects such as inductance and resistance, leading to improved signal integrity and faster circuit operation.

Front-end-of-line (FEOL) MIM capacitors, on the other hand, offers several advantages over their BEOL counterparts. FEOL MIM capacitors can be fabricated at an earlier stage in the manufacturing process, allowing for even smaller and more densely integrated components. Due to their proximity to active devices, FEOL MIM capacitors can offer lower parasitic effects and faster switching speeds. The earlier integration of FEOL MIM capacitors can potentially improve their long-term reliability and reduce the risk of defects. FEOL MIM capacitors can be tailored to specific capacitance values, enabling more precise circuit design and optimization.

As a result, FEOL MIM capacitors have great potential for various applications. FEOL MIM capacitors are well-suited for applications requiring high-speed, low-power, and small-size components. Their low parasitic effects and customizable capacitance make them ideal for analog circuits such as filters, amplifiers, and oscillators. FEOL MIM capacitors can be used in memory cells to improve performance and reduce power consumption.

FEOL MIM capacitors can also be used in CMOS Image Sensor (CIS) chips due to their unique properties and advantages. These capacitors play a crucial role in capturing and processing light signals, ensuring high-quality image and video output. FEOL MIM capacitors are ideal for applications requiring high-resolution images, such as smartphone cameras, surveillance cameras, and medical imaging systems. FEOL MIM capacitors can help to reduce noise in CIS chips, making them suitable for applications where low noise is critical, such as scientific imaging and night vision. The reduced parasitic effects of FEOL MIM capacitors can enable faster image capture and processing, making them suitable for applications requiring high frame rates, such as sports cameras and video surveillance.

However, there is always room for improvement. In particular, FEOL MIM capacitors fabricated by, for example, a dummy replacement approach, are influenced by fringe capacitance from nearby conductors (e.g., contacts, connectors, and the like). Fringe capacitance is an unintended capacitance that arises due to the overlapping electric fields between nearby conductors. In the case of FEOL MIM capacitors, fringe capacitance can occur between the top and bottom electrodes, as well as between the electrodes and other nearby structures such as interconnects or vias. Fringe capacitance can increase the total capacitance of the FEOL MIM capacitor beyond its intended value. This can lead to unexpected behavior in the circuit and affect its performance. Fringe capacitance can introduce parasitic effects, such as increased coupling between signals and reduced bandwidth. This can degrade the overall performance of the circuit. Accurately modeling and controlling fringe capacitance can be challenging, especially in complex chip designs with dense interconnects. Thus, there is a need for further reducing fringe capacitance in FEOL MIM capacitors.

In accordance with some aspects of the disclosure, a FEOL MIM capacitor is provided. In some embodiments, the metal contact (e.g., a via) is surrounded by an air spacer. In one implementation, the air spacer is formed by removing a dummy silicon layer surrounding the metal contact, and the air spacer is sealed by performing an ion implantation process to an interlayer dielectric (ILD) to cause volumetric expansion of the ILD. By surrounding the metal contact with an air spacer, the fringe capacitance between the metal contact and the metal layer of the FEOL MIM capacitor can be significantly reduced. In other embodiments, the MIM stack structure (sometimes also referred to as the “MG-equivalent structure”), instead of the metal contact is surround by an air spacer. Details of these features will be discussed below.

### Example FEOL MIM Capacitors and Example Fabrication Process Flows

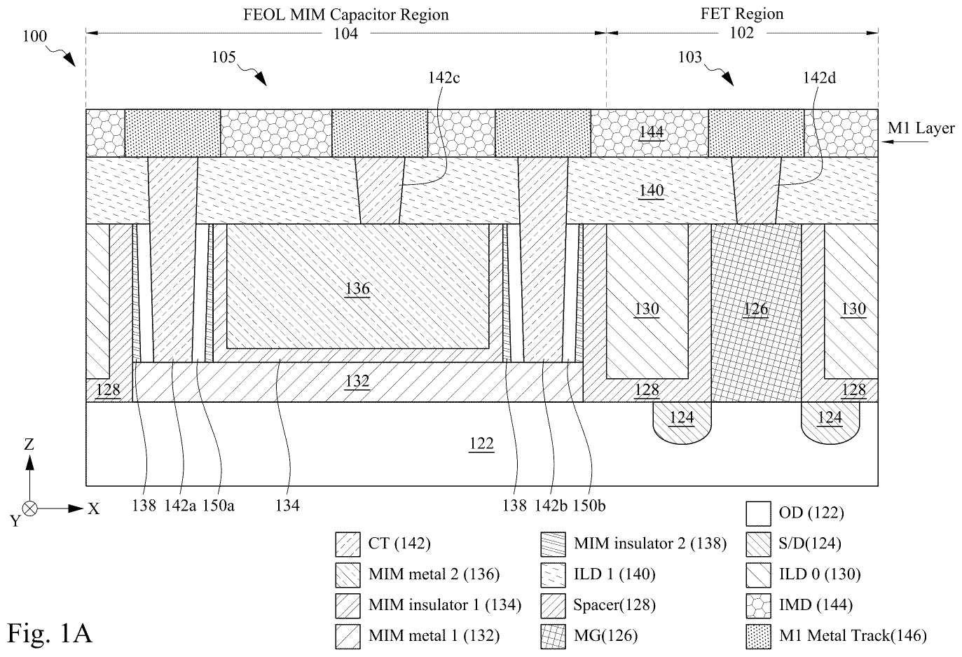

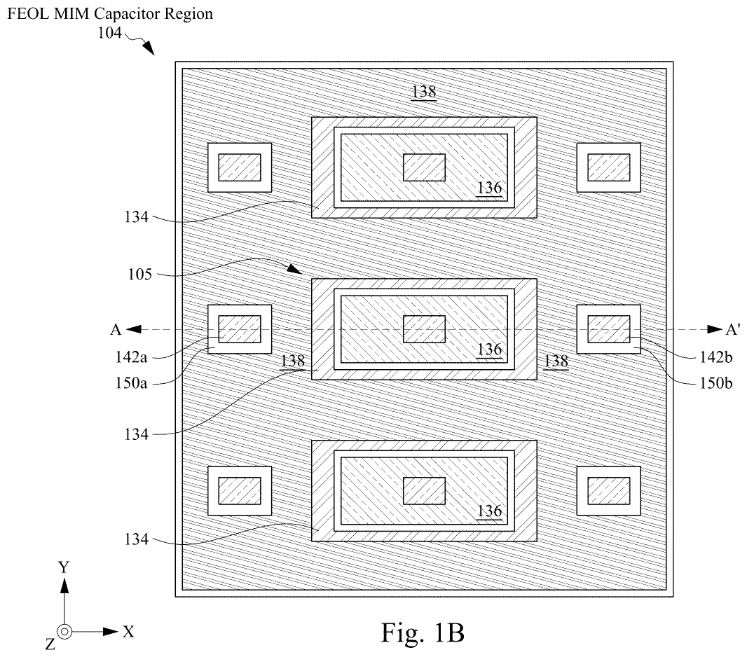

FIG. 1A is a cross-sectional diagram illustrating an example chip in accordance with some embodiments. FIG. 1B is a diagram illustrating a top view of a portion of the chip of FIG. 1A in accordance with some embodiments. It should be understood that FIGS. 1A and 1B not drawn to scale.

In the example shown in FIG. 1A, the chip 100 includes a FEOL MIM capacitor (or simply “MIM capacitor”) 105 and an FET 103 disposed in a substrate not shown. The MIM capacitor region is disposed in a FEOL MIM capacitor region 104, and the FET 103 is disposed in a FET region 102. The MIM capacitor 105 and the FET 103 are isolated by spacer structures 128 in this example. In some examples, the spacer structures 128 comprises silicon nitride (SiNx), Silicon Oxide (SiO₂), or other suitable materials.

Both the MIM capacitor 105 and the FET 102 are disposed on an oxide diffusion (“OD”) region 122 of the substrate. And both the MIM capacitor 105 and the FET 102 are disposed in a first interlay dielectric (labelled as “ILD 0” in FIG. 1A) 130. Thus, the MIM capacitor 105, like the FET 103, are fabricated using FEOL processing techniques. The MIM capacitor 105 is not a BEOL MIM capacitor mentioned above. A second interlayer dielectric (labelled as “ILD 1” in FIG. 1A) 140 is disposed above the first ILD 130. An intermetal dielectric (labelled as “IMD” shown in FIG. 1A) 144 is disposed on the second ILD 140. Since the first metal layer (i.e. “M1 layer”) metal tracks 146 are disposed in the IMD 144, the layer where the IMD 144 and the M1 layer metal tracks 146 are located is also called the “M1 layer.” Although not shown in FIG. 1A, one of ordinary skill in the art would appreciate that there are typically more layers, such as the M2 layer, the M3 layer, the M4 layer, etc., disposed on the M1 layer. As such, a multi-layer interconnect (MLI) structure is disposed over the MIM capacitor 104 and the FET 103 for routing. The MLI structure is fabricated using BEOL processing techniques.

The FET 103, in the example shown in FIG. 1A, is a planar MOSFET and includes a metal gate 126, two source/drain regions 124. In some examples, the metal gate 126 comprises titanium nitride (TiN) or tungsten (W), molybdenum (Mo), or other suitable materials. It should be understood that this is exemplary, and other types of FET may also be employed as needed. Some examples include FinFETs, GAAFETs, and CFETs. Although only one MIM capacitor 105 and one FET 103 are shown, it should be understood multiple (e.g., tens of, hundreds of, or even thousands of) MIM capacitors and FETs may be fabricated and integrated into one circuit to achieve a variety of functions as needed. Other passive devices and active devices may be employed as well. One of ordinary skill in the art would recognize many variations, modifications, and alternatives.

The MIM capacitor 105 includes, among other components, a first metal layer (labelled as “MIM metal 1” in FIG. 1A) 132, a second metal layer (labelled as “MIM metal 2” in FIG. 1A) 136, and a first insulator layer (labelled as “MIM insulator 1” in FIG. 1A) 134. The first metal layer 132 serves as a bottom electrode, whereas the second metal layer 136 serves as a top electrode. The first insulator layer 134 is characterized by a “U” shape and includes a horizontal portion and two sidewall portions. The horizontal portion of the first insulator layer 134 is disposed between the first metal layer 132 and the second metal layer 136. In other words, the horizontal portion of the first insulator layer 134 is sandwiched between the first metal layer 132 and the second metal layer 136. The sidewall portions of the first insulator layer 134 surround the second metal layer 136 (in the cross-section shown in FIG. 1A, at two sides of the second metal layer 136 in the X-direction). The top surface of the sidewall portions is coplanar with the top surface of the second metal layer 136 in the Z-direction. As such, the first metal layer 132, the first insulator layer 134, and the second metal layer 136 form a capacitor, i.e., the MIM capacitor 105.

A second insulator layer (labelled as “MIM insulator 2” in FIG. 1A) 138 surrounds the first insulator layer 134 (in the cross-section shown in FIG. 1A, at two sides of the first insulator layer 134 in the X-direction). The second insulator layer 138 is vertically disposed on the first metal layer 132. The second insulator layer 138 is characterized by two trenches, one trench is for accommodating a first metal contact (e.g., a via) 142a and the other trench is for accommodating a second metal contact (e.g., a via) 142b. The first metal contact 142a extends vertically in the Z-direction and penetrates through the second insulator layer 138. A bottom end of the first metal contact 142a is in contact with the first metal layer 132. Likewise, the second metal contact 142b extends vertically in the Z-direction and penetrates through the second insulator layer 138. A bottom end of the second metal contact 142b is in contact with the first metal layer 132. The first and second metal contacts 142a and 142b may comprise tungsten, copper, or other suitable materials.

Unlike conventional structures where the first metal contact 142a and the second metal contact 142b are in contact with the second insulator layer 138, the MIM capacitor 105 shown in FIG. 1A is characterized by a first air spacer 150a surrounding the first metal contact 142a and a second air spacer 150b surrounding the second metal contact 142b. In other words, the first metal contact 142a is not in direct contact with second insulator layer 138. Instead, the first air spacer 150a is disposed between them. Likewise, the second metal contact 142b is not in direct contact with second insulator layer 138. Instead, the second air spacer 150b is disposed between them.

Air has a lower dielectric constant (about 1.00059 at room temperature) compared to an insulator and most semiconductor materials. The dielectric constant is a measure of a material's ability to store electrical energy. A lower dielectric constant means less capacitance for a given area. As a result, the first air spacer 150a can significantly reduce the fringe capacitance between the first metal contact 142a and the second metal layer 136, whereas the second air spacer 150b can significantly reduce the fringe capacitance between the second metal contact 142b and the second metal layer 136.

Although the height of the first air spacer 150a is the same as the height of the second insulator layer 138 in the example shown in FIG. 1A, it should be understood that this doesn't have to be the case. In some embodiments, a top portion of the first air spacer 150a may be occupied by the second ILD 140 during fabrication. However, even in this situation, the first air spacer 150a still functions to reduce the fringe capacitance. In one example the height of the first air spacer 150a is more than 30% of the height of the second insulator layer 138. In another example, the height of the first air spacer 150a is more than 50% of the height of the second insulator layer 138. In another example, the height of the first air spacer 150a is more than 70% of the height of the second insulator layer 138. In another example, the height of the first air spacer 150a is more than 90% of the height of the second insulator layer 138.

Likewise, although the height of the second air spacer 150b is the same as the height of the second insulator layer 138 in the example shown in FIG. 1A, it should be understood that this doesn't have to be the case. In some embodiments, a top portion of the second air spacer 150b may be occupied by the second ILD 140 during fabrication. However, even in this situation, the second air spacer 150b still functions to reduce the fringe capacitance. In one example the height of the second air spacer 150b is more than 30% of the height of the second insulator layer 138. In another example, the height of the second air spacer 150b is more than 50% of the height of the second insulator layer 138. In another example, the height of the second air spacer 150b is more than 70% of the height of the second insulator layer 138. In another example, the height of the second air spacer 150b is more than 90% of the height of the second insulator layer 138.

As shown in FIG. 1B, the first air spacer 150a surrounds the first metal contact 142a, whereas the second air spacer 150b surrounds the second metal contact 142b. Although the horizontal cross-section of the first air spacer 150a and the second air spacer 150b is rectangular, it should be understood that other shapes (e.g., circle, ellipse, and the like) may be employed. One of ordinary skill in the art would recognize many variations, modifications, and alternatives. In addition, although two metal contacts are used for electrical connection to the first metal layer 132 in the example shown in FIGS. 1A and 1B, it should be understood that only one of them may be employed in other embodiments. One of ordinary skill in the art would recognize many variations, modifications, and alternatives.

Referring back to FIG. 1A, a metal contact 142c is disposed in the second ILD 140 for electrical connection to the second metal layer 136. In addition, a metal contact 142d is disposed in the second ILD 140 for electrical connection to the metal gate structure 126 of the FET 103. The first metal contact 142a, the second metal contact 142b, the metal contact 142c, and the metal contact 142d are electrically connected to M1 layer metal tracks 146 for further routing in the back end. In some examples, the M1 layer metal tracks 146 comprises copper or other suitable materials.

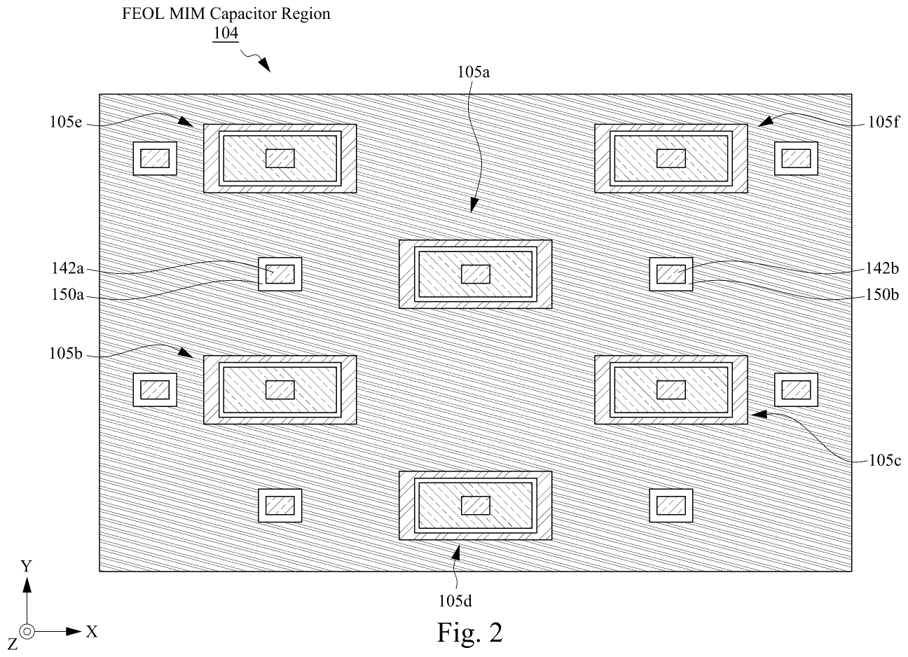

FIG. 2 is a diagram illustrating a top view of a portion of another chip in accordance with some embodiments. Unlike the embodiment shown in FIG. 1B where the MIM capacitors are aligned in the Y-direction, the MIM capacitors 150a, 150b, 150c, and 150d are arranged in a diamond configuration. The metal contacts (e.g., 142a and 142b) and corresponding air spacers (e.g., 150a and 150b) are arranged accordingly. As such, a high level of design flexibility can be achieved depending on the circumstances. One of ordinary skill in the art would recognize many variations, modifications, and alternatives.

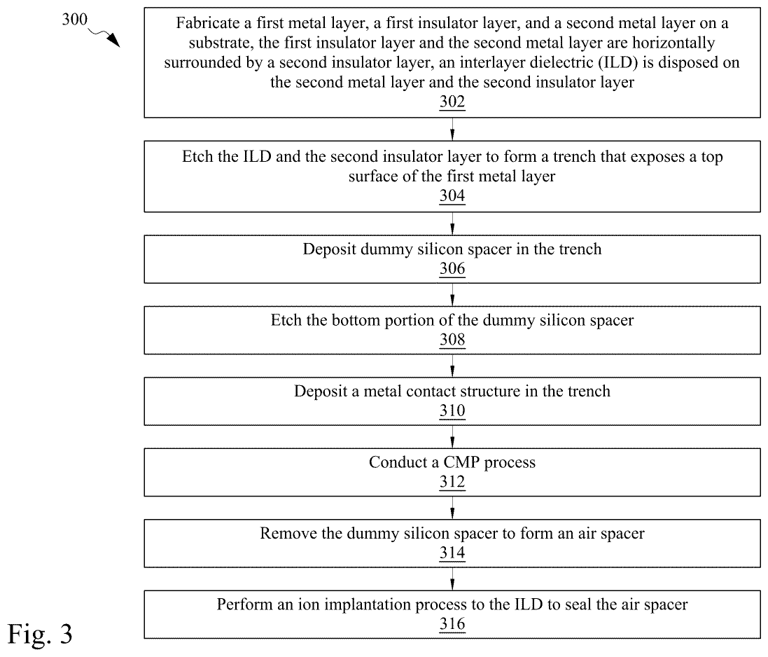

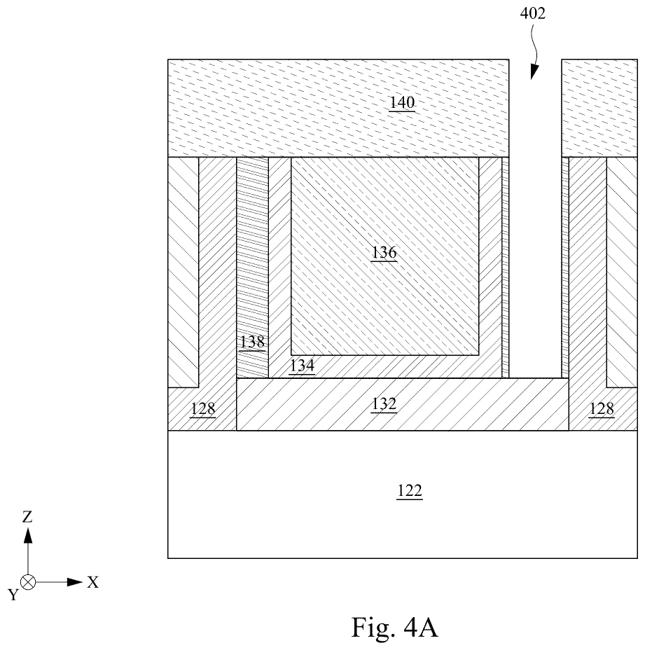

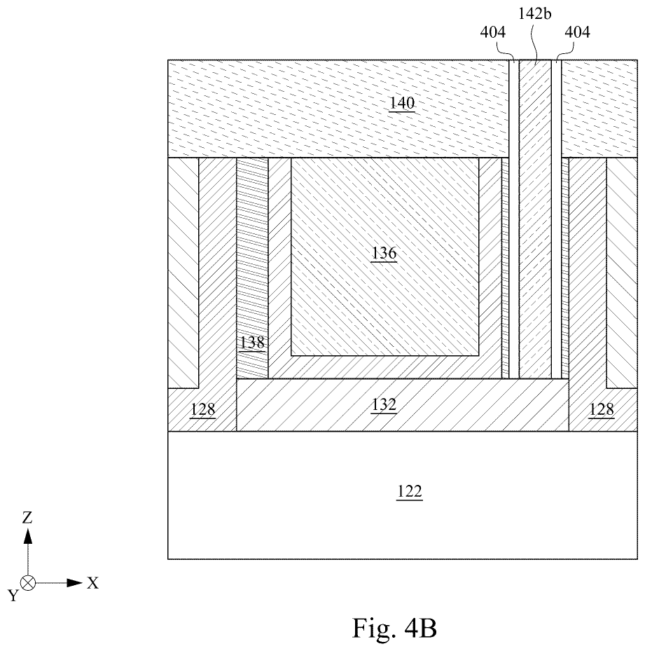

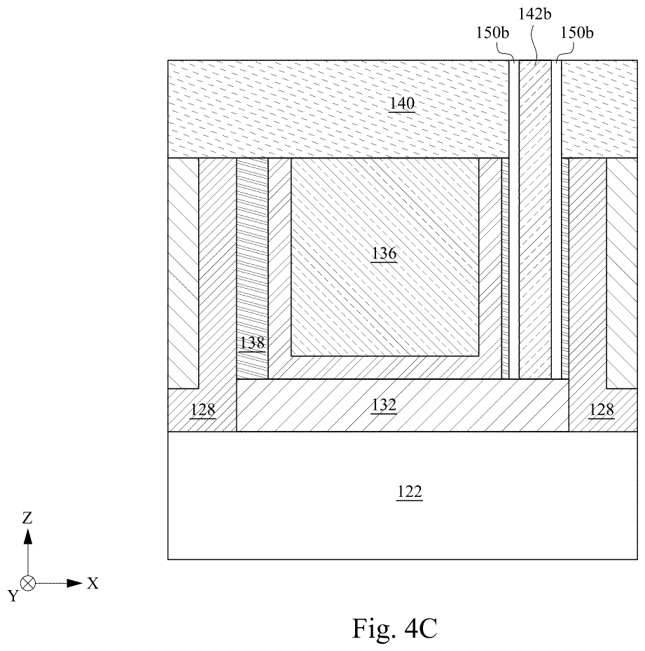

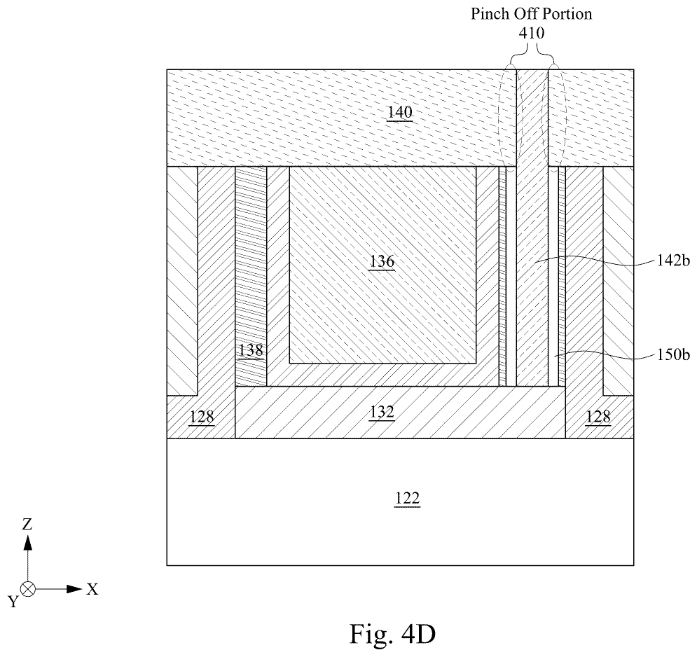

FIG. 3 is a flowchart diagram illustrating an example method 300 in accordance with some embodiments. FIGS. 4A-4D are cross-sectional diagrams illustrating the cross-sections of the structures in various fabrication stages in accordance with some embodiments. In the example shown in FIG. 3, the method 300 includes operations 302, 304, 306, 308, 310, 312, 314, and 316. Additional operations may be performed. Also, it should be understood that the sequence of the various operations discussed above with reference to FIG. 3 is provided for illustrative purposes, and as such, other embodiments may utilize different sequences. These various sequences of operations are to be included within the scope of embodiments.

At operation 302, a first metal layer 132, a first insulator layer 134, and a second metal layer 136 are fabricated on a substrate. In some examples, the first metal layer 132 and the second metal layer 136 may comprise titanium nitride (TiN), tantalum nitride (TaN), tungsten (W), aluminum (Al), or other suitable materials. In some examples, the first insulator layer 134 may comprise silicon dioxide (SiO₂), hafnium oxide (HfO₂), silicon nitride (Si₃N₄), or other suitable materials. The first insulator layer 134 and the second metal layer 136 are horizontally surrounded by a second insulator layer 138. An ILD (i.e., the second ILD 140) is disposed on the second metal layer 136 and the second insulator layer 138. Details of these layers have been described above with reference to FIGS. 1A-1B.

At operation 304, and as shown in FIG. 4A, the second ILD 140 and the second insulator layer 138 are etched to form a trench 402. The trench 402 extends vertically in the Z-direction from the top surface of the second ILD 140 to a top surface of the first metal layer 132. Therefore, the trench 402 exposes the top surface of the first metal layer 132, enabling fabricating the metal contact electrically connected to the first metal layer 132 in later stages. One of ordinary skill in the art would recognize many variations, modifications, and alternatives.

At operation 306, and as shown in FIG. 4B, a dummy silicon spacer 404 is formed in the trench 402. The dummy silicon spacer 404 is conformally formed in the trench 402, covering the bottom and sidewalls of the trench 402. The dummy silicon spacer 404 may be formed using techniques such as chemical vapor deposition (CVD) like atmospheric pressure CVD (APCVD), low-pressure CVD (LPCVD), plasma-enhanced CVD (PECVD), atomic layer deposition (ALD), and the like. One of ordinary skill in the art would recognize many variations, modifications, and alternatives.

At operation 308, and as shown in FIG. 4B, the bottom portion of the dummy silicon spacer 404 is etched to expose the top surface of the first metal layer 132. As such, metal contact electrically connected to the first metal layer 132 can be achieved in later stages. The bottom portion of the dummy silicon spacer 404 can be etched using techniques such as dry etching (e.g., plasma etching, reactive ion etching (RIE), deep RIE, etc.) or wet etching (e.g., anisotropic wet etching). One of ordinary skill in the art would recognize many variations, modifications, and alternatives.

At operation 310, and as shown in FIG. 4B, a metal contact layer 142b is deposited. The metal contact layer 142b fills in the trench 402. The metal contact layer 142b can be formed using techniques such as CVD (e.g., metalorganic CVD (MOCVD)), electroplating, ALD, physical vapor deposition (PVD), and the like. One of ordinary skill in the art would recognize many variations, modifications, and alternatives.

At operation 312, and as shown in FIG. 4B, a planarization process (e.g., CMP) is performed. After the planarization process, excessive portions of the dummy silicon spacer 404 and the metal contact layer 142b outside the trench 402 are removed, and the structure becomes what is shown in FIG. 4B. Specifically, the metal contact layer 142b becomes a metal contact (e.g., a via) 142b. One of ordinary skill in the art would recognize many variations, modifications, and alternatives.

At operation 314, and as shown in FIG. 4C, the dummy silicon spacer 404 is removed. After removing the dummy silicon spacer 404, the air spacer 150b is formed. As described above with reference to FIGS. 1A and 1B, the air spacer 150b horizontally surrounds the metal contact 142b, thereby mitigating the fringe capacitance. The dummy silicon spacer 404 can be removed using techniques such as wet etching (e.g., isotropic wet etching). Various types of etchants may be employed depending on factors like selectivity, uniformity, and contamination. Examples of etchants may include ammonia solution (NH3OH), KOH (Potassium Hydroxide), TMAH (Tetramethylammonium Hydroxide), HF (Hydrofluoric acid). One of ordinary skill in the art would recognize many variations, modifications, and alternatives.

At operation 316, and as shown in FIG. 4D, an ion implantation process is performed to the ILD 140 to seal the air spacer 150b. In some implementations, dopants such as xenon (Xe) and germanium (Ge) are implanted into the ILD 140. When dopants are implanted to the ILD 140 comprising, for example, silicon dioxide, local stresses are created due to the large atomic radius of such dopants (e.g., Xe and Ge). The local stresses in the ILD 140 causes volumetric expansion of the ILD 140 through mechanisms such as lattice distortion and expansion. As a result, a pinch off portion 410 is formed as a result of the volumetric expansion, and the air spacer 150b is sealed at its top. It should be understood that during this “sealing” process, the volumetric expansion may be both horizontal and vertical. Thus, the height of the air spacer 150b may decrease as a result of the vertical volumetric expansion. One of ordinary skill in the art would recognize many variations, modifications, and alternatives.

It should be understood that although only one metal contact is illustrated in the example shown in FIGS. 4A-4D, two or more metal contacts can be fabricated similarly. One of ordinary skill in the art would recognize many variations, modifications, and alternatives.

It should also be noted that other steps may follow to achieve more complicated structural features. For example, M1 layer can be fabricated afterwards for routing. One of ordinary skill in the art would recognize many variations, modifications, and alternatives.

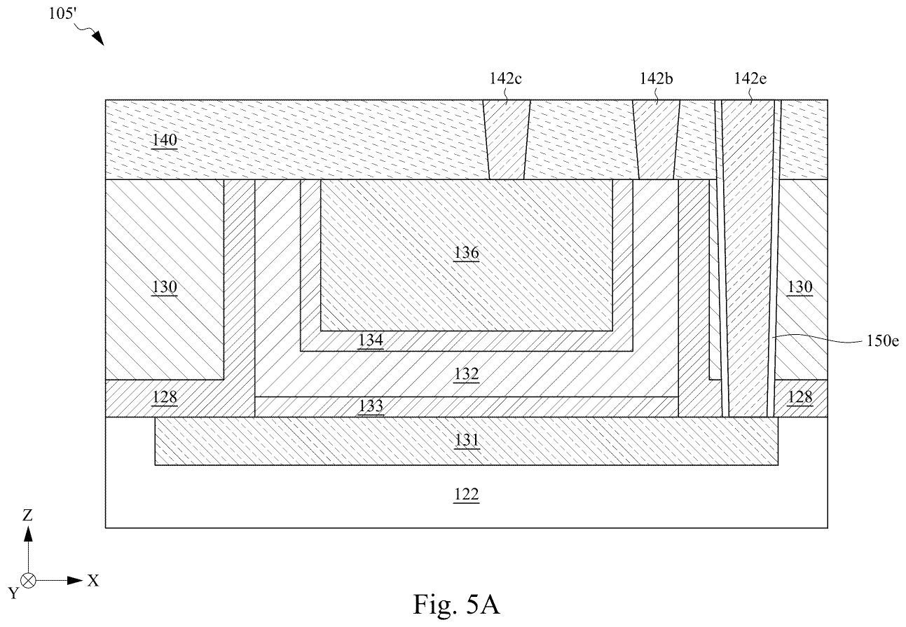

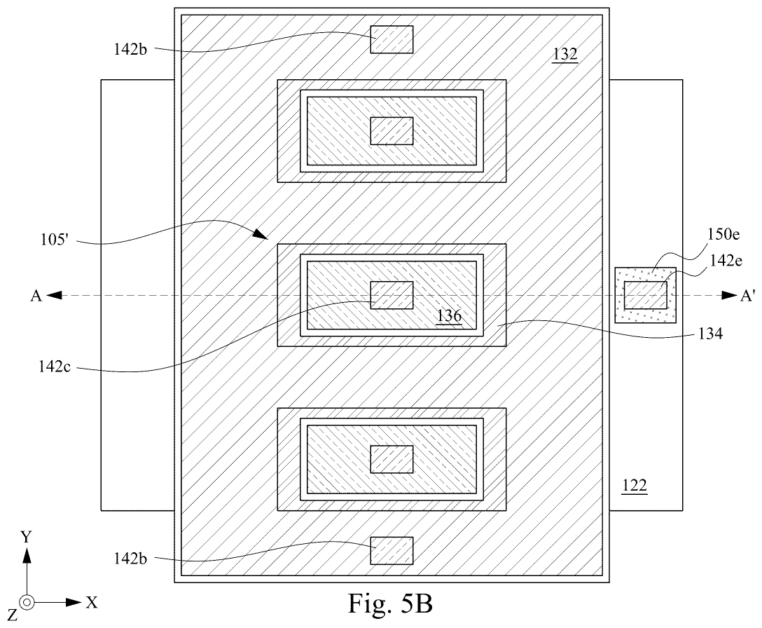

FIG. 5A is a cross-sectional diagram illustrating an example chip in accordance with some embodiments. FIG. 5B is a diagram illustrating a top view of a portion of the chip of FIG. 5A in accordance with some embodiments. It should be understood that FIGS. 5A and 5B not drawn to scale.

Like the example shown in FIGS. 1A and 1B, the chip includes a FEOL MIM capacitor (or simply “MIM capacitor”) 105′. Therefore, the same features are not repeated in the description of FIGS. 5A and 5B with reference to FIGS. 5A and 5B.

The major distinction is that the MIM capacitor 105′ is characterized by a five-layer structure instead of a three-layer structure. Specifically, in addition to the first metal layer 132, the second metal layer 136, and the first insulator layer 134, the MIM capacitor 105′ further includes a third metal layer 131 and the third insulator layer 133, in the manner shown in FIG. 5A. Metal contacts (e.g., vias) 142c, 142b, and 142e are electrically connected to the second metal layer 136, the first metal layer 132, and the third metal layer 131, respectively. The third metal layer 131 is embedded in the oxide diffusion (“OD”) region 122 of the substrate. A top surface of the third metal layer 131 is coplanar with the top surface of the OD region 122. The third insulator layer 133 is disposed between the first metal layer 132 and the third metal layer 131. Unlike the embodiment shown in FIG. 1A, the first metal layer 132 has sidewall portions in the manner shown in FIG. 5A for easy routing accessibility.

Likewise, the metal contact 142e is in contact with the top surface of the third metal layer 131. Unlike conventional structures, the MIM capacitor 105′ is characterized by an air spacer 150e surrounding the metal contact 142e. In other words, the metal contact 142e is not in direct contact with the ILD 130. Air has a lower dielectric constant (about 1.00059 at room temperature) compared to an insulator and most semiconductor materials. As a result, the air spacer 150e can significantly reduce the fringe capacitance between the metal contact 142e and the second insulator layer 138 and the first metal layer 132.

Although the height of the air spacer 150e is the same as the sum of the height of the first ILD 130 and the spacer 128 in the example shown in FIG. 5A, it should be understood that this doesn't have to be the case. In some embodiments, a top portion of the air spacer 150e may be occupied by the second ILD 140 during fabrication. However, even in this situation, the air spacer 150e still functions to reduce the fringe capacitance. In one example the height of the air spacer 150e is more than 30%, 50%, 70%, or 90% of the height of the sum of the height of the first ILD 130 and the spacer 128.

As shown in FIG. 5B, the first air spacer 150e surrounds the metal contact 142e. Although the horizontal cross-section of the air spacer 150e is rectangular, it should be understood that other shapes (e.g., circle, ellipse, and the like). One of ordinary skill in the art would recognize many variations, modifications, and alternatives. In addition, although only one metal contact is used for electrical connection to the third metal layer 131 in the example shown in FIGS. 5A and 5B, it should be understood that more than one (e.g., two) may be employed in other embodiments. One of ordinary skill in the art would recognize many variations, modifications, and alternatives. One of ordinary skill in the art would also appreciate that the fabrication process flow is similar to that shown in FIGS. 3 and 4A-4D. It should also be noted that similar MIM capacitors with more than five layers (e.g., a seven-layer structure) can be fabricated similarly.

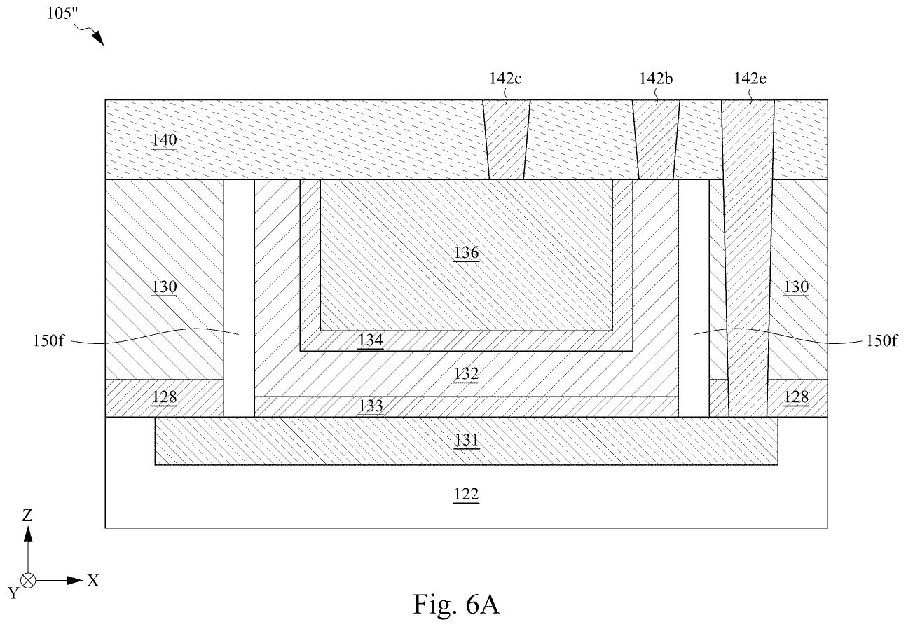

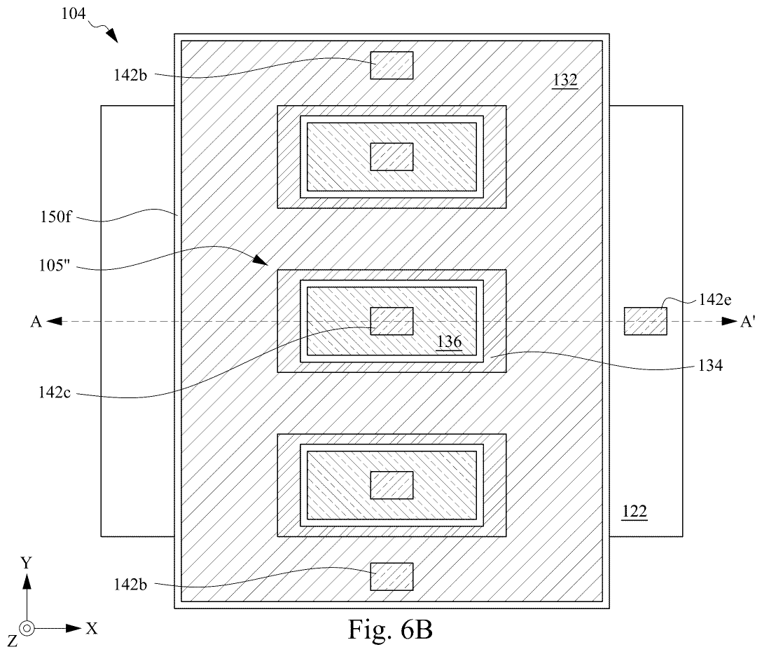

FIG. 6A is a cross-sectional diagram illustrating an example chip in accordance with some embodiments. FIG. 6B is a diagram illustrating a top view of a portion of the chip of FIG. 6A in accordance with some embodiments. It should be understood that FIGS. 6A and 6B are not drawn to scale.

Like the example shown in FIGS. 1A and 1B, the chip includes a FEOL MIM capacitor (or simply “MIM capacitor”) 105″. Therefore, the same features are not repeated in the description of FIGS. 6A and 6B with reference to FIGS. 6A and 6B.

One of the major distinctions is that the MIM capacitor 105″ is characterized by a five-layer structure instead of a three-layer structure. Specifically, in addition to the first metal layer 132, the second metal layer 136, and the first insulator layer 134, the MIM capacitor 105″ further includes a third metal layer 131 and a third insulator layer 133, in the manner shown in FIG. 6A. Metal contacts (e.g., vias) 142c, 142b, and 142e are electrically connected to the second metal layer 136, the first metal layer 132, and the third metal layer 131, respectively. The third metal layer 131 is embedded in the oxide diffusion (“OD”) region 122 of the substrate. A top surface of the third metal layer 131 is coplanar with the top surface of the OD region 122. The third insulator layer 133 is disposed between the first metal layer 132 and the third metal layer 131. Unlike the embodiment shown in FIG. 1A, the first metal layer 132 has sidewall portions in the manner shown in FIG. 5A for easy routing accessibility.

Another major distinction is the location of the air spacer 150f. Unlike the embodiment shown in FIGS. 5A and 5B where the spacer 128 includes a sidewall portion, the spacer 128 in the embodiment shown in FIG. 6A does not include a sidewall portion. Instead, the air spacer 150f horizontally surrounds the first metal layer 132. The sidewall portion of the first metal layer 132 is contact with the air spacer 150f, therefore not in contact with the first ILD 130. On the other hand, the air spacer 150f does not horizontally surround the metal contact 142e.

Since air has a lower dielectric constant (about 1.00059 at room temperature) compared to an insulator and most semiconductor materials. As a result, the air spacer 150f can significantly reduce the fringe capacitance between the metal contact 142e and the first metal layer 132. As such, the air spacer 150f still functions to reduce the fringe capacitance despite that it is disposed at a different location. Because the underlying principle of the air spaer 150f stays unchanged.

Although the height of the air spacer 150f is the same as the sum of the height of the first ILD 130 and the spacer 128 in the example shown in FIG. 6A, it should be understood that this doesn't have to be the case. In some embodiments, a top portion of the air spacer 150f may be occupied by the second ILD 140 during fabrication. However, even in this situation, the air spacer 150f still functions to reduce the fringe capacitance. In one example the height of the air spacer 150f is more than 30%, 50%, 70%, or 90% of the height of the sum of the height of the first ILD 130 and the spacer 128.

As shown in FIG. 6B, the air spacer 150f surrounds the first metal layer 132, not the metal contact 142e. Although the horizontal cross-section of the air spacer 150f is rectangular, it should be understood that other shapes (e.g., circle, ellipse, and the like) may be employed. One of ordinary skill in the art would recognize many variations, modifications, and alternatives. In addition, although only one metal contact is used for electrical connection to the third metal layer 131 in the example shown in FIGS. 6A and 6B, it should be understood that more than one (e.g., two) may be employed in other embodiments. One of ordinary skill in the art would recognize many variations, modifications, and alternatives. It should also be noted that similar MIM capacitors with more than five layers (e.g., a seven-layer structure) can be fabricated similarly.

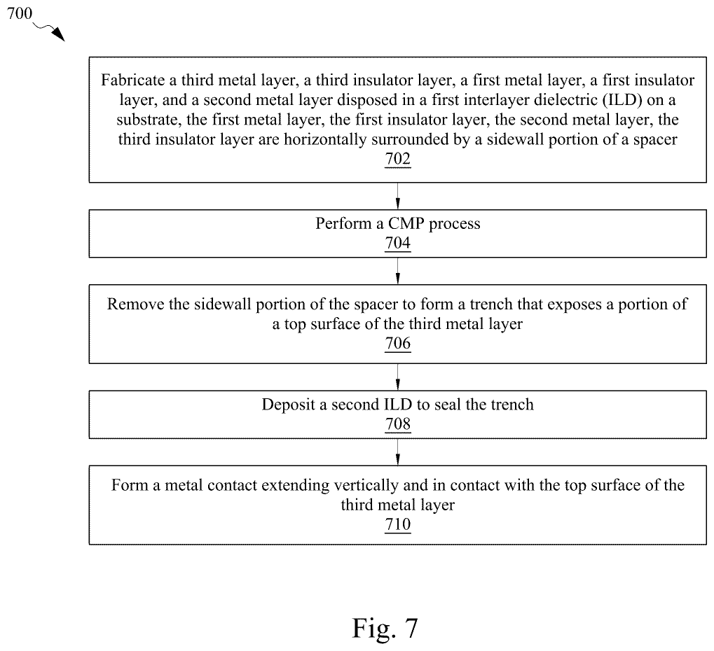

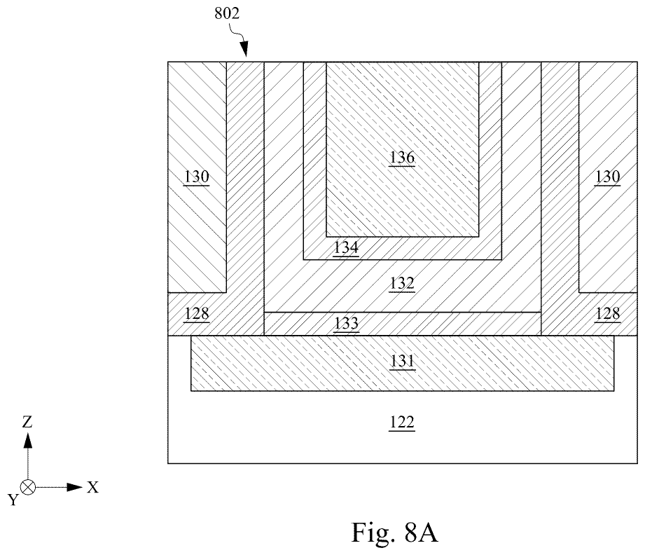

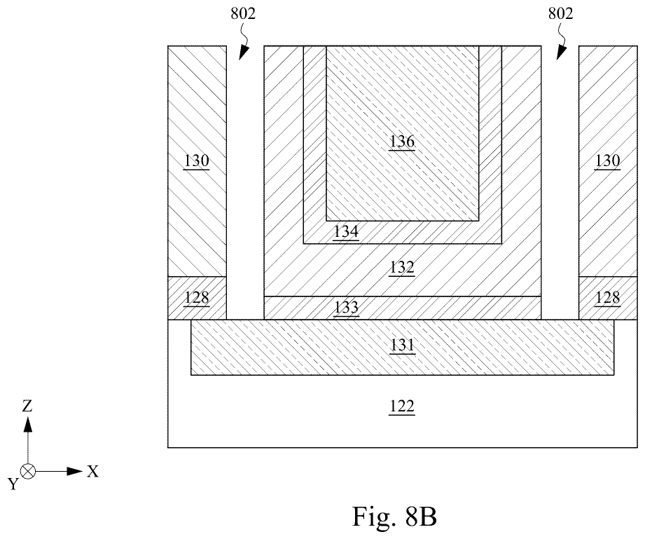

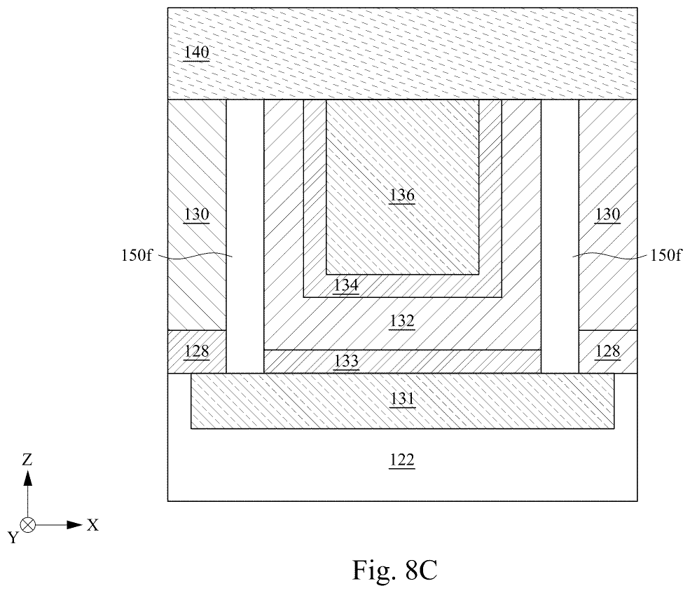

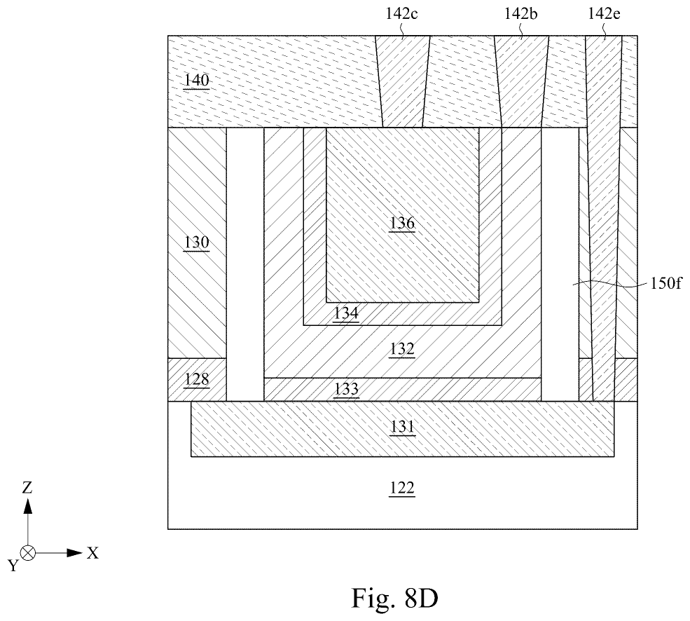

FIG. 7 is a flowchart diagram illustrating an example method 700 in accordance with some embodiments. FIGS. 8A-8D are cross-sectional diagrams illustrating the cross-sections of the structures in various fabrication stages in accordance with some embodiments. In the example shown in FIG. 7, the method 300 includes operations 702, 704, 706, 708, and 710. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 702, and as shown in FIG. 8A, a five-layer structure 802 is fabricated in the first ILD 130 disposed on the substrate. The five-layer structure includes the first metal layer 132, the first insulator layer 134, the second metal layer 136, the third metal layer 131, and the third insulator layer 133. A spacer 128 is disposed conformally on the five-layer structure 802. Details of these layers have been described above with reference to FIGS. 6A-6B.

At operation 704, and as shown in FIG. 8A, a planarization process (e.g., CMP) is performed. After the planarization process, the top portion of the spacer 128 on the five-layer structure 802 is removed. The sidewall portion of the spacer 128 horizontally surrounds the first metal layer 132, the first insulator layer 134, the second metal layer 136, and the third insulator layer 133 in the manner shown in FIG. 8A. One of ordinary skill in the art would recognize many variations, modifications, and alternatives.

At operation 706, and as shown in FIG. 8B, the sidewall portion of the spacer 128 is removed. After the sidewall portion of the spacer 128 is removed, a trench 802 is formed. The trench 802 exposes a portion of the top surface of the third metal layer 131 and surrounds the first metal layer 132 and the third insulator layer 133. As will be described below, the trench 802 will be sealed at its top in later stages to from the air spacer 150f shown in FIG. 6A. In some embodiments, the spacer 128 comprises silicon nitride (SiN), silicon oxynitride (SiNON), silicon carbonitride (SiCN), silicon oxycarbonitride (SiOCN), or dummy Si. In some implementations, the sidewall portion of the spacer 128 is removed using techniques such as wet etching (e.g., anisotropic wet etching). One of ordinary skill in the art would recognize many variations, modifications, and alternatives.

At operation 708, and as shown in FIG. 8C, the second ILD 140 is deposited on the top of the structure. Since the trench 802 is characterized by a high aspect ratio, the second ILD 140 seals the trench 802 from the top to form the air spacer 150f. In some implementations, the second ILD 140 is deposited using techniques such as CVD, PECVD, sputtering, ALD, and the like. One of ordinary skill in the art would recognize many variations, modifications, and alternatives. It should be understood that the second ILD 140 may fill the trench 802 to some extent, and the height of the air spacer 150f is smaller than the height of the trench 802. One of ordinary skill in the art would recognize many variations, modifications, and alternatives.

At operation 710, and as shown in FIG. 8D, the metal contact 142e is formed. The metal contact 142e extends vertically from the top surface of the second ILD 140 to the top surface of the third metal layer 131, thereby providing electrical connection to the third metal layer 131. In some implementations, the metal contact 142e is formed by lithography followed by etching the second ILD 140, the first ILD 130 and the bottom portion of the spacer 128. The metal contact 142e is then formed using techniques such as such as CVD (e.g., metalorganic CVD (MOCVD)), electroplating, ALD, physical vapor deposition (PVD), and the like. One of ordinary skill in the art would recognize many variations, modifications, and alternatives. It should be understood that the metal contacts 142b and 142c may be formed in a similar manner.

### SUMMARY

In accordance with some aspects of the disclosure, a semiconductor device is provided. The semiconductor device includes: a substrate; a first interlayer dielectric (ILD) disposed on the substrate; and a metal-insulator-metal (MIM) capacitor disposed in the first ILD. The MIM capacitor comprises: a first metal layer disposed on the substrate; a first insulator layer comprising a horizontal portion and a sidewall portion; a second metal layer, wherein the horizontal portion of the first insulator layer is disposed between the first metal layer and the second metal layer, and the sidewall portion of the first insulator layer horizontally surrounding the second metal layer; a second insulator layer surrounding the sidewall portion of the first insulation layer; at least one metal contact extending vertically through the second insulator layer, wherein a lower end of the at least one metal contact is in contact with a top surface of the first metal layer; and at least one air spacer horizontally surrounding the at least one metal contact.

In accordance with some aspects of the disclosure, a method is provided. The method comprises: fabricating a metal-insulator-metal (MIM) capacitor in a first interlayer dielectric (ILD) disposed on a substrate, wherein the MIM capacitor comprises: a first metal layer disposed on the substrate; a first insulator layer comprising a horizontal portion and a sidewall portion; a second metal layer, wherein the horizontal portion of the first insulator layer is disposed between the first metal layer and the second metal layer, and the sidewall portion of the first insulator layer horizontally surrounding the second metal layer; and a second insulator layer surrounding the sidewall portion of the first insulation layer; depositing a second ILD on the first ILD; etching the second ILD and the second insulator layer to form a trench, exposing a portion of a top surface of the first metal layer; forming a dummy silicon spacer in the trench; etching a bottom portion of the dummy silicon spacer to expose the portion of the top surface of the first metal layer; depositing a metal contact layer to fill the trench; performing a planarization process; removing the dummy silicon spacer to form an air spacer horizontally surrounding the metal contact layer in the trench; and performing an ion implantation process to the second ILD to seal the air spacer.

In accordance with some aspects of the disclosure, a semiconductor device is provided. The semiconductor device includes: a substrate; a first interlayer dielectric (ILD) disposed on the substrate; and a metal-insulator-metal (MIM) capacitor disposed in the first ILD. The MIM capacitor comprises: a third metal layer disposed on the substrate; a third insulator layer disposed on the third metal layer; a first metal layer disposed on the third insulator layer and comprising a horizontal portion and a sidewall portion; a first insulator layer comprising a horizontal portion and a sidewall portion, the sidewall portion of the first metal layer horizontally surrounding the sidewall portion of the first insulator portion; a second metal layer, wherein the horizontal portion of the first insulator layer is disposed between the first metal layer and the second metal layer, and the sidewall portion of the first insulator layer horizontally surrounding the second metal layer; at least one metal contact extending vertically through the first ILD, wherein a lower end of the at least one metal contact is in contact with a top surface of the third metal layer; and an air spacer horizontally surrounding the sidewall portion of the first metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first interlayer dielectric (ILD) disposed on the substrate; and
a metal-insulator-metal (MIM) capacitor disposed in the first ILD, the MIM capacitor comprising:
a first metal layer disposed on the substrate;
a first insulator layer comprising a horizontal portion and a sidewall portion;
a second metal layer, wherein the horizontal portion of the first insulator layer is disposed between the first metal layer and the second metal layer, and the sidewall portion of the first insulator layer horizontally surrounding the second metal layer;
a second insulator layer surrounding the sidewall portion of the first insulation layer;
at least one metal contact extending vertically through the second insulator layer, wherein a lower end of the at least one metal contact is in contact with a top surface of the first metal layer; and
at least one air spacer horizontally surrounding the at least one metal contact.

2. The semiconductor device of claim 1, wherein a height of the air spacer is greater than 30% of a height of the second insulator layer.

3. The semiconductor device of claim 1, wherein a height of the air spacer is greater than 90% of a height of the second insulator layer.

4. The semiconductor device of claim 1, further comprising:
a second ILD disposed on the first ILD.

5. The semiconductor device of claim 4, wherein the second ILD seals the at least one air spacer at a top portion of the at least one air spacer.

6. The semiconductor device of claim 1, wherein the second ILD is characterized by at least one dopant.

7. The semiconductor device of claim 6, wherein the at least one dopant comprises xenon (Xe).

8. The semiconductor device of claim 6, wherein the at least one dopant comprises germanium (Ge).

9. The semiconductor device of claim 1, wherein a top surface of the second metal layer is coplanar with a top surface of the sidewall portion of the first insulator layer.

10. The semiconductor device of claim 1, wherein a width of the first metal layer is larger than a width of the horizontal portion of the first insulator layer.

11. A method, comprising:
fabricating a metal-insulator-metal (MIM) capacitor in a first interlayer dielectric (ILD) disposed on a substrate, wherein the MIM capacitor comprises:
a first metal layer disposed on the substrate;
a first insulator layer comprising a horizontal portion and a sidewall portion;
a second metal layer, wherein the horizontal portion of the first insulator layer is disposed between the first metal layer and the second metal layer, and the sidewall portion of the first insulator layer horizontally surrounding the second metal layer; and
a second insulator layer surrounding the sidewall portion of the first insulation layer;
depositing a second ILD on the first ILD;
etching the second ILD and the second insulator layer to form a trench, exposing a portion of a top surface of the first metal layer;
forming a dummy silicon spacer in the trench;
etching a bottom portion of the dummy silicon spacer to expose the portion of the top surface of the first metal layer;
depositing a metal contact layer to fill the trench;
performing a planarization process;
removing the dummy silicon spacer to form an air spacer horizontally surrounding the metal contact layer in the trench; and
performing an ion implantation process to the second ILD to seal the air spacer.

12. The method of claim 11, wherein forming the dummy silicon spacer comprises:
conformally forming the dummy silicon spacer on the trench.

13. The method of claim 11, wherein a lower end of the metal contact layer in the trench is in contact with the portion of the top surface of the first metal layer.

14. The method of claim 11, wherein the planarization process removes an excessive portion of the dummy silicon spacer and the metal contact layer outside the trench.

15. The method of claim 11, wherein removing the dummy silicon spacer comprises:
etching the dummy silicon spacer using a wet etching process.

16. The method of claim 11, wherein the ion implantation process introduces at least a dopant in the second ILD.

17. The method of claim 16, wherein the at least one dopant comprises xenon (Xe).

18. The method of claim 16, wherein the at least one dopant comprises germanium (Ge).

19. A semiconductor device, comprising:
a substrate;
a first interlayer dielectric (ILD) disposed on the substrate; and
a metal-insulator-metal (MIM) capacitor disposed in the first ILD, the MIM capacitor comprising:
a third metal layer disposed on the substrate;
a third insulator layer disposed on the third metal layer;
a first metal layer disposed on the third insulator layer and comprising a horizontal portion and a sidewall portion;
a first insulator layer comprising a horizontal portion and a sidewall portion, the sidewall portion of the first metal layer horizontally surrounding the sidewall portion of the first insulator portion;
a second metal layer, wherein the horizontal portion of the first insulator layer is disposed between the first metal layer and the second metal layer, and the sidewall portion of the first insulator layer horizontally surrounding the second metal layer;
at least one metal contact extending vertically through the first ILD, wherein a lower end of the at least one metal contact is in contact with a top surface of the third metal layer; and
an air spacer horizontally surrounding the sidewall portion of the first metal layer.

20. The semiconductor device of claim 19, further comprising:
a second ILD disposed on the first ILD, and wherein the second ILD seals the air spacer at a top portion of the air spacer.
